(19) United States
(12) Patent Application Publication
(10) Pub. No.: US 2025/0320115 A1
(43) Pub. Date: Oct. 16, 2025

(54) MEMS DEVICES SINGULATED BY PLASMA ETCH

(71) Applicant: TEXAS INSTRUMENTS INCORPORATED, Dallas, TX (US)

(72) Inventors: Lawrence Hawthorne JACOB, Garland, TX (US); John Charles EHMKE, Longview, TX (US)

(21) Appl. No.: 18/930,841

(22) Filed: Oct. 29, 2024

Related U.S. Application Data
(60) Provisional application No. 63/634,016, filed on Apr. 15, 2024.

(51) Int. Cl. B81B 7/00; B81C 1/00

(52) U.S. Cl. CPC B81B 7/007; B81C 1/00301; B81B 2201/042; B81B 2203/0315; B81B 2207/07; B81C 2201/0112; B81C 2201/0132; B81C 2203/019; B81C 2203/038

(57) ABSTRACT

In examples, an electronic device includes a semiconductor die including circuitry, a microelectromechanical systems (MEMS) element on the semiconductor die and coupled to the circuitry, a bond pad on the semiconductor die and coupled to the circuitry, and a bondline on the semiconductor die between the MEMS element and the bond pad, with the bondline circumscribing the MEMS element. The electronic device includes a semiconductor interposer coupled to the bondline and having a striated exterior surface facing away from the MEMS element.

### CROSS-REFERENCE TO RELATED APPLICATIONS

The present application claims priority to U.S. Provisional Patent Application No. 63/634,016, which was filed Apr. 15, 2024, is titled “MECHANICAL PLASMA OVERBURDEN REMOVAL,” and is hereby incorporated herein by reference in its entirety.

### BACKGROUND

Semiconductor chips are often housed inside semiconductor packages that protect the chips from deleterious environmental influences, such as heat, moisture, and debris. A packaged chip communicates with electronic devices outside the package via conductive terminals, such as leads, that are exposed to surfaces of the package. Within the package, the chip may be electrically coupled to the conductive terminals using any suitable technique, such as by wire bonding.

### SUMMARY

In examples, an electronic device includes a semiconductor die including circuitry, a microelectromechanical systems (MEMS) element on the semiconductor die and coupled to the circuitry, a bond pad on the semiconductor die and coupled to the circuitry, and a bondline on the semiconductor die between the MEMS element and the bond pad, with the bondline circumscribing the MEMS element. The electronic device includes a semiconductor interposer coupled to the bondline and having a striated exterior surface facing away from the MEMS element.

In examples, a method for manufacturing a microelectromechanical systems (MEMS) device includes sawing through a first portion of a semiconductor interposer to form a first opening, the semiconductor interposer coupled to one or more oxide layers, the one or more oxide layers coupled to a bondline, the bondline coupled to a semiconductor wafer, the bondline circumscribing a MEMS element on the semiconductor wafer, the bondline between the MEMS element and a first bond pad on the semiconductor wafer; plasma etching through a second portion of the semiconductor interposer using the first opening to form a second opening; forming a third opening in the one or more oxide layers using the first and second openings to expose the first bond pad; and sawing through the semiconductor wafer between the first bond pad and a second bond pad on the semiconductor wafer.

### BRIEF DESCRIPTION OF THE DRAWINGS

FIG. 1A is a block diagram of an electronic system containing a MEMS device manufactured in accordance with various examples described herein.

FIG. 1B is a top-down view of an electronic system containing a MEMS device manufactured in accordance with various examples described herein.

FIGS. 2A-2E are cross-sectional, top-down, perspective, profile, and profile views, respectively, of a MEMS device manufactured in accordance with various examples described herein.

FIGS. 3A-3C are cross-sectional, profile, and perspective views of a MEMS device manufactured in accordance with various examples described herein.

FIGS. 4A-4C are cross-sectional, profile, and perspective views of a MEMS device manufactured in accordance with various examples described herein.

FIGS. 5A and 5B are profile views of striations formed on a MEMS device manufactured in accordance with various examples described herein.

FIG. 6 is a flow diagram of a method for manufacturing a MEMS device in accordance with various examples described herein.

FIGS. 7A-14B are process flow diagrams for manufacturing a MEMS device in accordance with various examples described herein.

FIGS. 15A-17B are process flow diagrams for manufacturing a MEMS device in accordance with various examples described herein.

### DETAILED DESCRIPTION

Prior to inclusion in a semiconductor package, a semiconductor die is produced by singulating a semiconductor wafer. Some wafers are readily singulated, for example, using a sawing or laser technique. However, some wafers are specifically formed for specialized applications, as is the case with certain microelectromechanical systems (MEMS) devices. For example, some MEMS devices include a semiconductor wafer having multiple mirrors positioned thereupon and having a glass wafer positioned above the mirrors by multiple interposers. The glass wafer protects the underlying mirrors. Such a structure is readily singulated by using a saw or laser process to cut through the glass wafer, the interposer layer, and miscellaneous layers (e.g., oxide layers). However, cutting completely through the entire thickness of the interposer is risky, as the saw can easily damage the bond pad shelf that is directly below the interposer. To mitigate this risk, the saw is used to cut through most, but not all, of the interposer, and the remainder of the interposer is removed using a special tool that is inserted into the column formed by the saw cut and rocked back and forth until the interposer is dislodged. While this technique helps to mitigate some of the risk to the bond pad shelf underlying the interposer, substantial risk to the bond pad shelf still remains, and manufacturing yield remains suboptimal.

Described herein are various examples of a MEMS device manufacturing technique by which the technical challenges described above are resolved. Specifically, the technique described herein significantly mitigates the risk of physical damage to MEMS device bond pad shelf during the wafer singulation process and substantially increases manufacturing yield. In examples, a method for manufacturing a microelectromechanical systems (MEMS) device includes sawing through a first portion of a semiconductor interposer (which, as used herein, is a semiconductor member that provides a standoff height to separate components from each other in the vertical direction) to form a first opening, where the semiconductor interposer is coupled to one or more oxide layers, the one or more oxide layers are coupled to a bondline, and the bondline is coupled to a semiconductor wafer. The bondline circumscribes a MEMS element on the semiconductor wafer, and the bondline is between the MEMS element and a first bond pad on the semiconductor wafer. The method also includes plasma etching through a second portion of the semiconductor interposer using the first opening to form a second opening. The method includes forming a third opening in the one or more oxide layers using the first and second openings to expose the first bond pad, such as by using a plasma etching technique or a liquid jet technique. The method includes sawing through the semiconductor wafer between the first bond pad and a second bond pad on the semiconductor wafer. The resulting semiconductor package (e.g., MEMS device) bears physical evidence that the above-described technique was used to manufacture the package. In particular, specific external surfaces of the semiconductor interposer and, in some examples, specific external surfaces of oxide layers below the semiconductor interposer are striated, indicating that the above-described plasma etch technique was used. In some examples, specific external surfaces of the semiconductor interposer are striated, but the external surfaces of the oxide layers below the semiconductor interposer are not striated, because the plasma etch technique was used to cut through the striated portion of the semiconductor interposer, and because the liquid jet technique was used to cut through the non-striated oxide layers below the semiconductor interposer. The techniques described herein are useful in the manufacture of various types of semiconductor devices, including a wide range of MEMS devices, such as optical and non-optical MEMS devices.

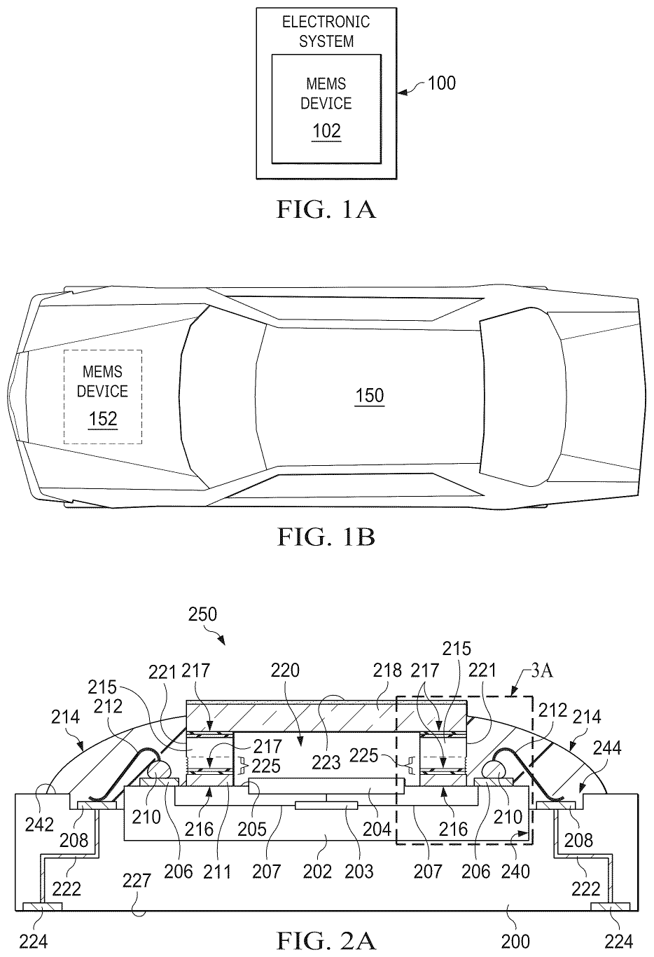

FIG. 1A is a block diagram of an electronic system containing a MEMS device manufactured in accordance with various examples described herein. Specifically, FIG. 1A depicts an electronic system 100 including a MEMS device 102. The electronic system 100 may be any type of system or device that may benefit from the inclusion of a MEMS device. Examples of the electronic system 100 include projection systems, automobiles, aircrafts, watercrafts, spacecrafts, video game consoles, smartphones, entertainment devices, appliances, laptop computers, desktop computers, tablets, notebooks, artificial intelligence (AI) devices, or any other suitable type of system or device. The MEMS device 102 may be any suitable type of MEMS device, such as optical devices (e.g., devices containing micromirror arrays), accelerometers, gyroscopes, sensors, microphones, resonators, etc. FIG. 1B is a top-down view of a vehicle 150 containing a MEMS device 152 manufactured in accordance with various examples described herein. The MEMS device 152 may be an example of the MEMS device 102 (FIG. 1A). The vehicle 150 may be a gas-powered vehicle, an electric vehicle (EV), or a hybrid vehicle. The MEMS device 152 may serve any useful purpose within the vehicle 150, for example, as part of a projector within a head-up display (HUD) of the vehicle 150, or as part of headlights, internal displays, window displays, and/or ground displays of the vehicle 150. Although FIG. 1B depicts the vehicle 150 as being an automobile, the vehicle 150 may be any suitable type of vehicle, such as an automobile, aircraft, watercraft, or spacecraft.

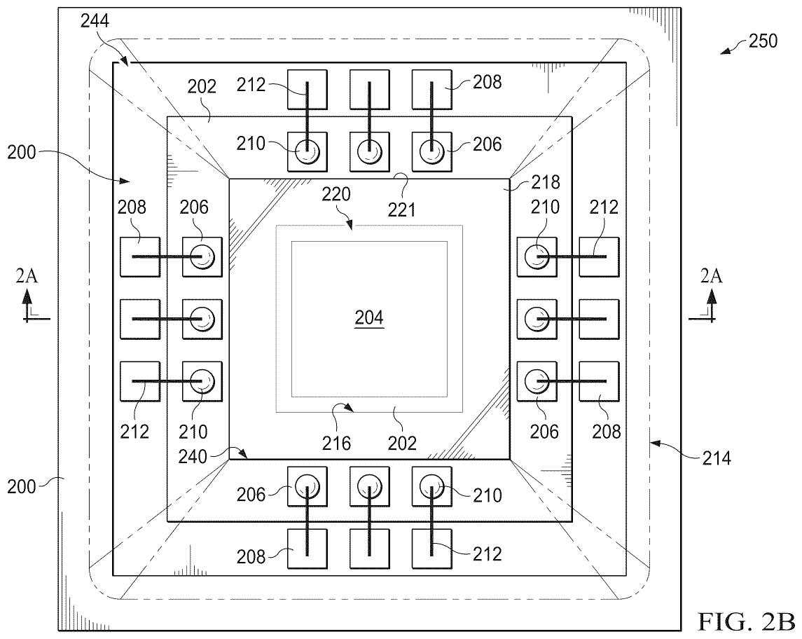

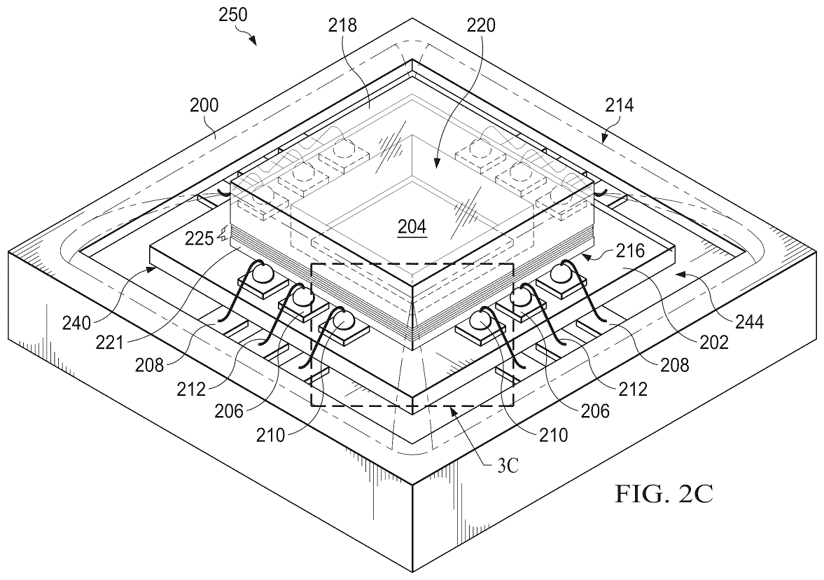

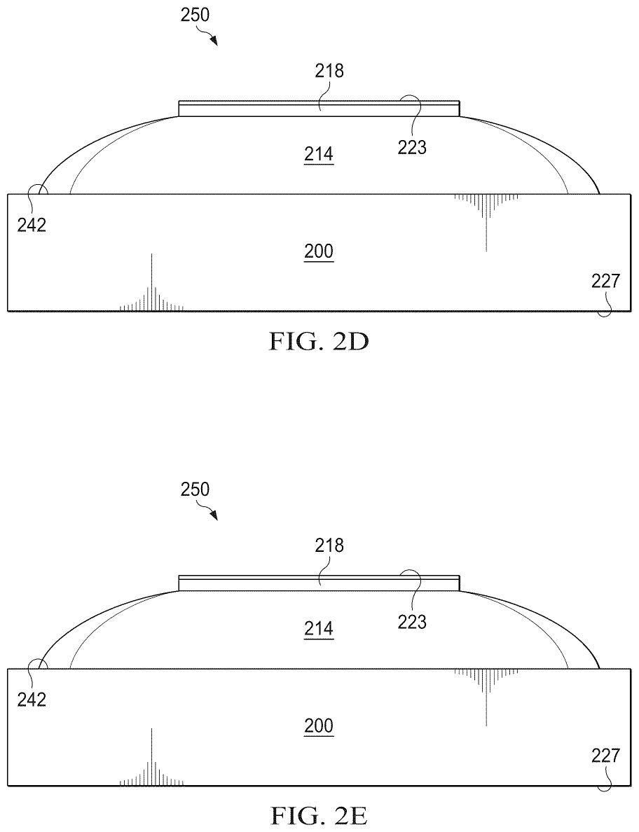

FIGS. 2A-2E are cross-sectional, top-down, perspective, profile, and profile views, respectively, of a MEMS device 250 manufactured in accordance with various examples described herein. The MEMS device 250 is a representative example of the MEMS devices 102 and 152 of FIGS. 1A and 1B, respectively. The MEMS device 250 includes a substrate 200, which in some examples may be a ceramic substrate. The MEMS device 102 includes a semiconductor die 202 on the substrate 200. The semiconductor die 202 may include circuitry 203 (e.g., complementary metal oxide semiconductor (CMOS) circuitry) on a device side 205 of the semiconductor die 202. Further, the semiconductor die 202 may include one or more devices 204 on the device side 205 of the semiconductor die 202. The one or more devices 204 may include additional circuitry (e.g., complementary metal oxide semiconductor (CMOS) circuitry), one or more mirrors, other MEMS mechanical devices, etc. that may be susceptible to damage by moisture, salt, debris, and other external contaminants. The circuitry 203 may be coupled to the one or more devices 204 and may control operational aspects of the one or more devices 204. The MEMS device 250 includes bond pads 206 and bond leads 208 on the substrate 200. The bond pads 206 are coupled to the circuitry 203 by traces 207. Bond wires 212 are coupled to the bond pads 206 by ball bonds 210 and are coupled to the bond leads 208 by, e.g., stitch bonds. In some examples, the bond pads 206 are located along two opposing sides of the semiconductor die 202, with the bond pads 206 absent from the remaining two sides of the semiconductor die 202.

An epoxy 214 covers various components of the MEMS device 250, such as the bond pads 206, bond leads 208, the ball bonds 210, the bond wires 212, and portions of the substrate 200. The epoxy 214 contacts and partially covers, but may not encapsulate, the substrate 200. In some examples, the epoxy 214 encapsulates the substrate 200, and in some examples, the epoxy 214 covers all areas of the top surface of the substrate 200 that are not otherwise covered by other components.

The epoxy 214 also contacts and covers a multi-sided (e.g., four-sided) structure 216 that extends approximately orthogonally from the device side 205 in the vertical direction and circumscribes the one or more devices 204. The epoxy 214 contacts and partially covers a cap 218 (e.g., a glass panel) that is coupled to the structure 216. The cap 218 is approximately parallel to the semiconductor die 202. The structure 216 may include, for instance, a bondline 211, an interposer 215 (e.g., a semiconductor interposer), and miscellaneous layers 217 (e.g., oxide layers, anti-reflective coatings) that, together with the cap 218, form a seal (e.g., a hermetic seal) enclosing a cavity 220. The epoxy 214 contacts and covers an outer surface 221 of the structure 216 that faces away from the cavity 220. The epoxy 214 contacts and covers part of the cap 218, but in examples, the epoxy 214 does not contact or cover any portion of a top surface 223 of the cap 218. The epoxy 214 seals the various components that the epoxy 214 contacts and covers and is fluid-resistant, protecting such components from moisture, debris, and other damaging environmental influences. The epoxy 214 is especially useful to protect the bond wires 212.

The epoxy 214 may be a glob top epoxy, a mold compound, or any other suitable epoxy or non-epoxy material that serves the purposes and performs the functions attributed herein to the epoxy 214. The epoxy 214 may be composed of at least 80% silica, which is useful because a composition lower than 80% silica may present technical disadvantages such as the application of mechanical and/or thermal stress to the MEMS device 250 that can damage various components of the MEMS device 250 (e.g., cracking of the cap 218, breaking and/or lifting of bond wires 212, cracking of the substrate 200). The epoxy 214 may have a coefficient of thermal expansion below 25, with a coefficient of thermal expansion at or above 25 possibly presenting technical disadvantages, such as the application of mechanical and/or thermal stress to the MEMS device 250 that can damage various components of the MEMS device 250 (e.g., cracking of the cap 218, breaking and/or lifting of bond wires 212, cracking of the substrate 200). The epoxy 214 may have a thickness adequate to cover all metals, alloys, and oxides in the structure 216, as well as the bond wires 212. Covering the structure 216 may include covering most or all of the outer surface 221 (e.g., including any orifices, interfaces between layers, and metal surfaces), as well as the interface between the structure 216 and the cap 218. A thickness of the epoxy 214 that fails to cover most or all (e.g., including any orifices, interfaces between layers, and metal surfaces) of the outer surface 221 as well as the interface between the structure 216 and the cap 218 may be technically disadvantageous because the structure 216, and particularly the metals in the structure 216, can be vulnerable to corrosion and/or oxidation, and because the MEMS device 250 may become vulnerable to infiltration and damage by external contaminants, such as salt, moisture, etc. However, if the epoxy 214 is so thick that the epoxy 214 covers substantially more than the outer surface 221 and the interface between the structure 216 and the cap 218, this thickness may become technically disadvantageous by adding expense and bulk without commensurate benefit, and by possibly covering some or all of the top surface of the cap 218 in optical applications (e.g., if the cap 218 is a glass panel). Further, an excess of epoxy 214 in the lateral direction (i.e., covering more of the substrate 200 than necessary) can cause challenges in deploying the MEMS device 250 in certain systems, such as those systems that use parts of the substrate 200 as optical reference points to ensure that the MEMS device 250 is properly seated and aligned within the system. In some examples, the bond wires 212 and epoxy 214 are located along only two sides of the semiconductor die 202, with the bond wires 212 and epoxy 214 being absent from the remaining two sides of the semiconductor die 202.

The substrate 200 includes a metal trace 222 that is coupled to the bond lead 208 and to a metal contact 224 on an exterior and/or bottom surface 227 of the substrate 200. The metal trace 222, the bond lead 208, the bond wire 212, the ball bond 210, and the bond pad 206 establish an electrical pathway between the metal contact 224 and circuitry 203 of the semiconductor die 202.

The outer surface 221 of the structure 216 bears physical marks that indicate the manufacturing technique described herein was used to manufacture the MEMS device 250. In particular, a portion of the outer surface 221 proximal to the semiconductor die 202 includes structural features known as striations 225. The striations 225 are formed as a result of using plasma etching (e.g., a Bosch process) to manufacture the MEMS device 250, as described below. The outer surface 221 also may be referred to herein as a striated outer surface 221. The specific portions of the outer surface 221 that bear the striations 225 depends on the specific manufacturing technique used, as described below. The disclosed techniques may be useful to form example devices when using a non-Bosch plasma etch process. Such example devices may lack striations.

In examples, the MEMS device 250 includes a cavity 240 in which the semiconductor die 202 is positioned. However, in other examples, the cavity 240 may be omitted, and the semiconductor die 202 may be placed on a flat surface that is horizontally coplanar with other surfaces within the MEMS device 250, such as a surface 242 or a shelf 244. In examples, the bond leads 208 are positioned on the shelf 244, which circumscribes the semiconductor die 202. However, in examples, the shelf 244 may be omitted, and the bond leads 208 may be positioned elsewhere, such as on the surface 242.

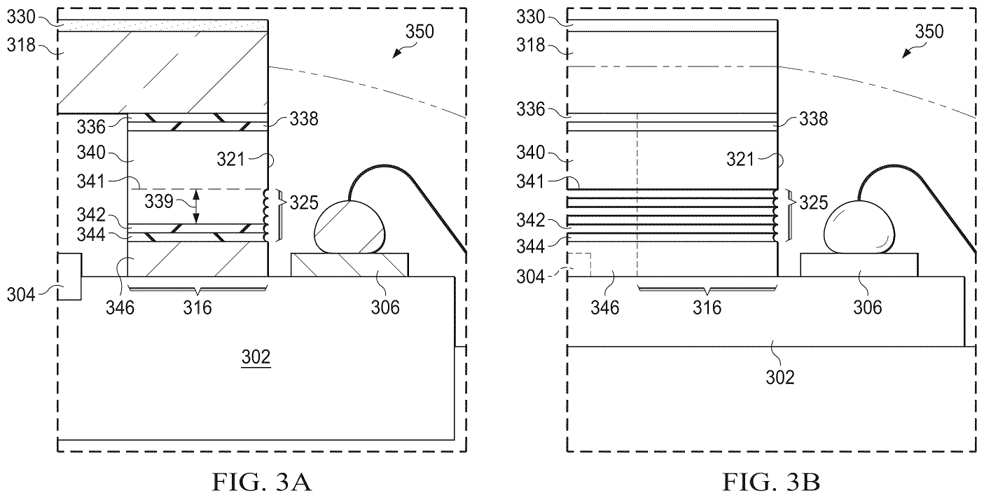

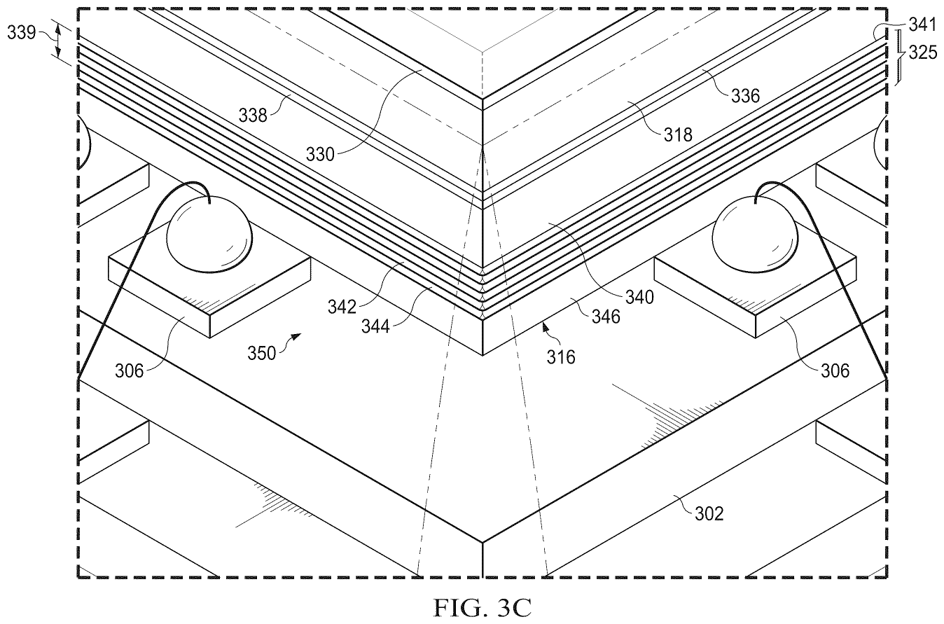

FIGS. 3A-3C are cross-sectional, profile, and perspective views of a MEMS device manufactured in accordance with various examples described herein. In particular, FIGS. 3A-3C provide a more detailed view of specific example components that may be included in the structure 216. FIG. 3A is a cross-sectional view of a portion of a MEMS device 350, which is representative of the MEMS devices 102, 152, and 250. The MEMS device 350 may include a semiconductor die 302 and a bond pad 306 on the semiconductor die 302, which are representative of the semiconductor die 202 and the bond pads 206 described above. The MEMS device 350 may include a structure 316, which is representative of the structure 216 described above. The structure 316 may circumscribe one or more devices 304, which is representative of the one or more devices 204 (FIG. 2). The MEMS device 350 may include a glass cap 318 (e.g., a glass panel), which is representative of the cap 218 described above.

The structure 316 may include an oxide layer 336 (e.g., plasma enhanced chemical vapor deposition (PECVD) oxide) and an oxide layer 338 (e.g., thermal oxide) contacting the oxide layer 336. The combined thickness of the oxide layers 336, 338 may be approximately 0.01 microns to 10 microns, with a combined thickness greater than this range possibly being disadvantageous because of increased wafer stress, and with a combined thickness less than this range possibly being disadvantageous because of manufacturing challenges. The structure 316 may include a semiconductor (e.g., silicon) interposer 340 contacting the oxide layer 338. The structure 316 may include an oxide layer 342 (e.g., thermal oxide) contacting the semiconductor interposer 340 and/or an oxide layer 344 (e.g., PECVD oxide) contacting the oxide layer 342. The combined thickness of the oxide layers 342, 344 is approximately 1 micron to 10 microns, with a combined thickness greater than this range being disadvantageous due to wafer stress and with a combined thickness less than this range being disadvantageous because of a reduction or absence of an etch stop margin. The structure 316 may include a bondline 346, which, in turn, may include any of a variety of metals, alloys, epoxies, photoresists, and/or composite materials. The bondline 346 may contact the oxide layer 344 and the semiconductor die 302.

The MEMS device 350 also includes the glass cap 318 (e.g., borosilicate glass) and coating layer 330 (e.g., an anti-reflective layer, an oxide layer, an etch resist layer) on the glass cap 318. The coating layer 330 and the glass cap 318 may be considered as part of the structure 316. Alternatively, the structure 316 may be considered as including the oxide layers 336, 338, the semiconductor interposer 340, the oxide layers 342, 344, and the bondline 346, with the coating layer 330 and the glass cap 318 being considered separate from the structure 316.

The structure 316 has an exterior surface 321 that includes striations 325. The striations 325 are formed by the plasma etching process (e.g., a Bosch process) described herein used to form the MEMS device 350. As shown, the striations 325 are formed on the portion of the semiconductor interposer 340 most proximal to the semiconductor die 302. The striations 325 are also present on the oxide layers 342, 344. The striations 325 may not be present on the bondline 346. The striations 325 include multiple concavities, and each concavity may have an approximately semicircular cross-section and be approximately 50 nanometers in height. A distance 339 separates the oxide layer 342 from a boundary 341 between striated and non-striated segments of the semiconductor interposer 340. The distance 339 ranges from 1 micron to 925 microns, with a value below this range indicating a risk of damage to the bond pad 306 during manufacture due to proximity of the mechanical or laser saw to the bond pad 306, and with a value greater than this range being indicative of inefficient manufacturing processes that include the premature termination of the sawing process through the semiconductor interposer 340.

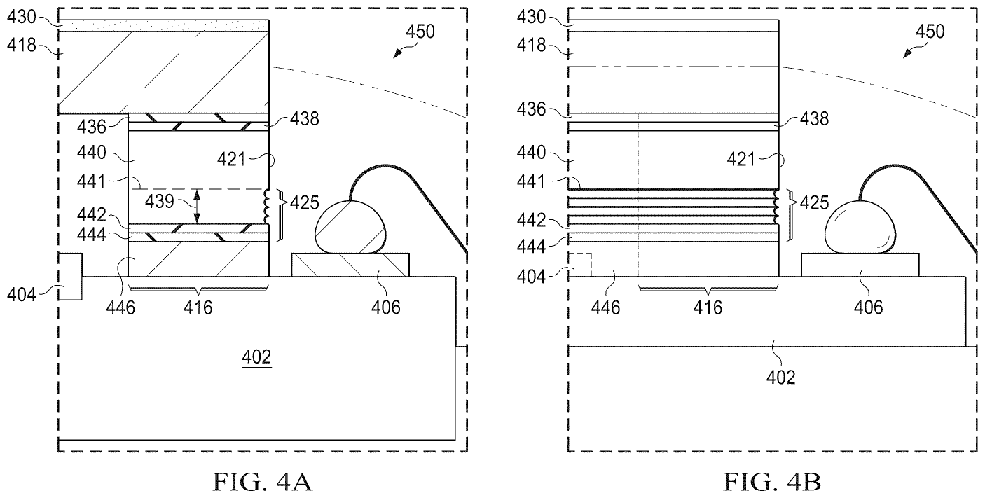

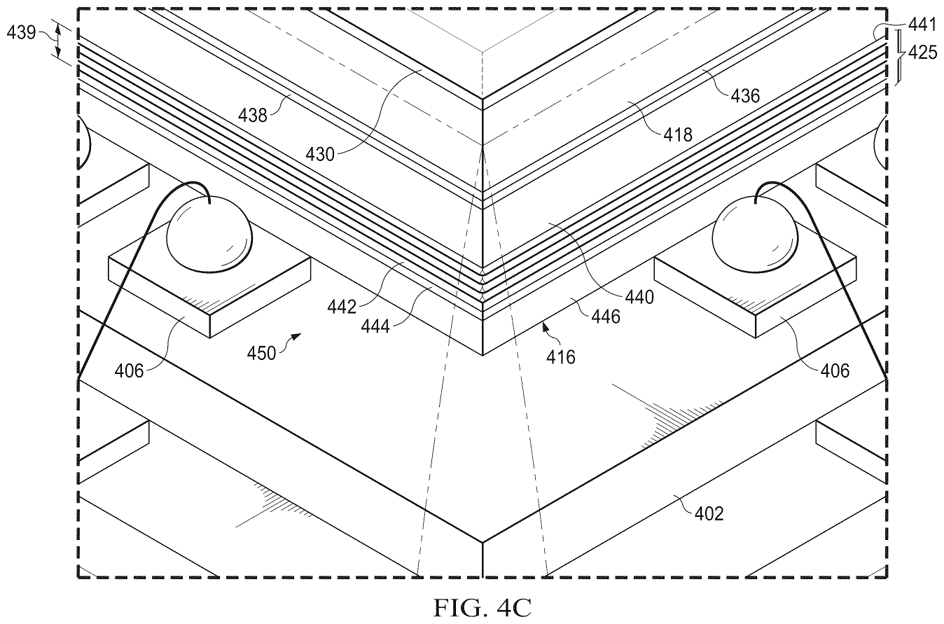

FIGS. 4A-4C are cross-sectional, profile, and perspective views of a MEMS device manufactured in accordance with various examples described herein. In particular, FIGS. 4A-4C provide a more detailed view of specific example components that may be included in the structure 216. FIG. 4A is a cross-sectional view of a portion of a MEMS device 450, which is representative of the MEMS devices 102, 152, and 250. The MEMS device 450 may include a semiconductor die 402 and a bond pad 406 on the semiconductor die 402, which are representative of the semiconductor die 202 and the bond pads 206 described above. The MEMS device 450 may include a structure 416, which is representative of the structure 216 described above. The structure 416 may circumscribe one or more devices 404, which is representative of the one or more devices 204 (FIG. 2). The MEMS device 450 may include a glass cap 418 (e.g., a glass panel), which is representative of the cap 218 described above.

The structure 416 may include an oxide layer 436 (e.g., plasma enhanced chemical vapor deposition (PECVD) oxide) and an oxide layer 438 (e.g., thermal oxide) contacting the oxide layer 436. The combined thickness of the oxide layers 436, 438 is approximately 0.01 microns to 10 microns, with a combined thickness greater than this range being disadvantageous because of substantially increased wafer stress, and with a combined thickness less than this range being disadvantageous because of manufacturing challenges. The structure 416 may include a semiconductor (e.g., silicon) interposer 440 contacting the oxide layer 438. The structure 416 may include an oxide layer 442 (e.g., thermal oxide) contacting the semiconductor interposer 440 and/or an oxide layer 444 (e.g., PECVD oxide) contacting the oxide layer 442. The combined thickness of the oxide layers 442, 444 is approximately 1.5 nanometers to 10 microns, with a combined thickness greater than this range being disadvantageous due to wafer stress, and with a combined thickness less than this range being disadvantageous because of an absence or reduction of an etch stop margin. The structure 416 may include a bondline 446, which, in turn, may include any of a variety of metals, alloys, epoxies, photoresists, and/or composite materials. The bondline 446 may contact the oxide layer 444 and the semiconductor die 402.

The MEMS device 450 also includes the glass cap 418 (e.g., borosilicate glass) and coating layer 430 (e.g., an anti-reflective layer, an oxide layer, an etch resist layer) on opposing sides of the glass cap 418. The coating layer 430 and the glass cap 418 may be considered as part of the structure 416. Alternatively, the structure 416 may be considered as including the oxide layers 436, 438, the semiconductor interposer 440, the oxide layers 442, 444, and the bondline 446, with the coating layer 430 and the glass cap 418 being considered separate from the structure 416.

The structure 416 has an exterior surface 421 that includes striations 425. The striations 425 are formed by the plasma etching process (e.g., a Bosch process) described herein used to form the MEMS device 450. As shown, the striations 425 are formed on the portion of the semiconductor interposer 440 most proximal to the semiconductor die 402. Unlike the striations 325 in FIGS. 3A-3C, the striations 425 are not present on the oxide layers 442 or 444. The striations 425 may not be present on the bondline 446. The striations 425 include multiple concavities, and each concavity may have an approximately semicircular cross-section and be approximately 50 nanometers in height. A distance 439 separates the oxide layer 442 from a boundary 441 between striated and non-striated segments of the semiconductor interposer 440. The distance 439 ranges from 1 micron to 925 microns, with a value below this range indicating a risk of damage to the bond pad 406 during manufacture due to proximity of the mechanical or laser saw to the bond pad 406, and with a value greater than this range being indicative of inefficient manufacturing processes that include the premature termination of the sawing process through the semiconductor interposer 440.

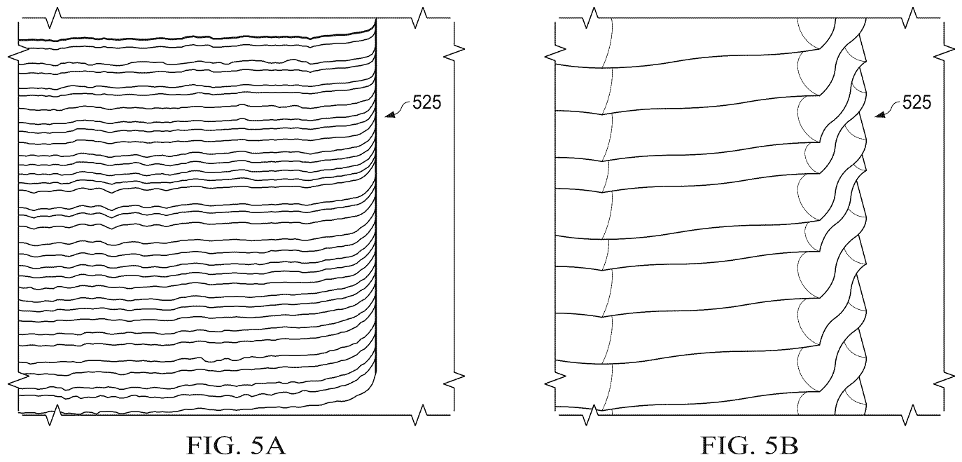

FIGS. 5A and 5B are profile views of striations 525 formed on a MEMS device manufactured in accordance with various examples described herein. The striations 525 are representative of the striations 325 and 425 in FIGS. 3A-3C and 4A-4C, respectively. The striations are formed by the plasma etching process used to form the MEMS device, such as the MEMS devices 250, 350, and 450. As shown, the striations 525 includes multiple concavities having a roughly scalloped shape and having a roughly semi-circular cross-section. More particularly, the striations formed on walls subjected to the Bosch plasma etch process appear as a series of periodic, rounded notches. These scalloped features are caused by the alternating cycles of etching and passivation during the plasma etch process, resulting in a non-smooth, wavy texture on the walls, with distinct bulges corresponding to each cycle. The scallop size and depth can vary based on process parameters like etch time and passivation thickness.

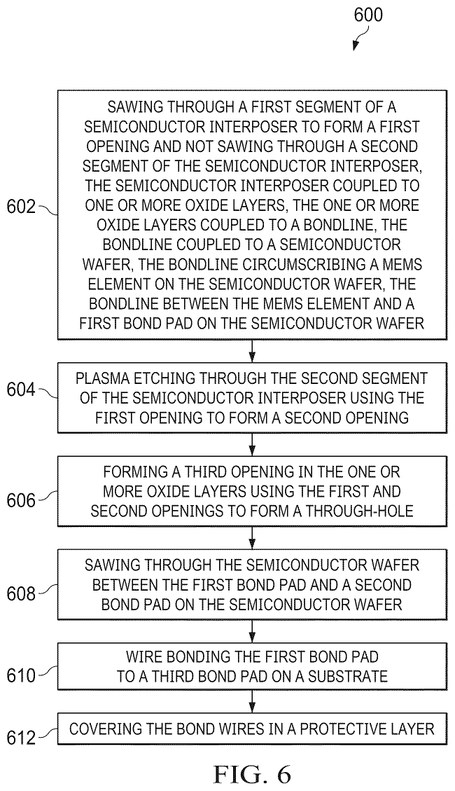

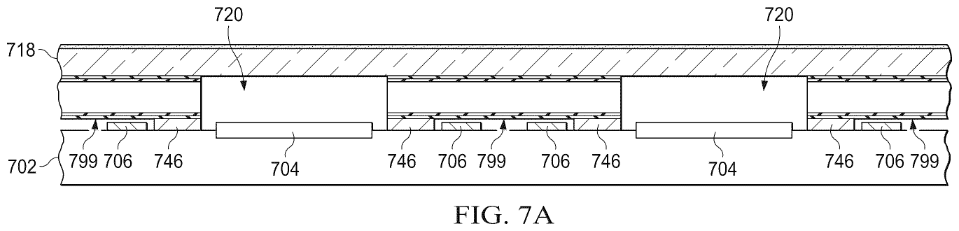

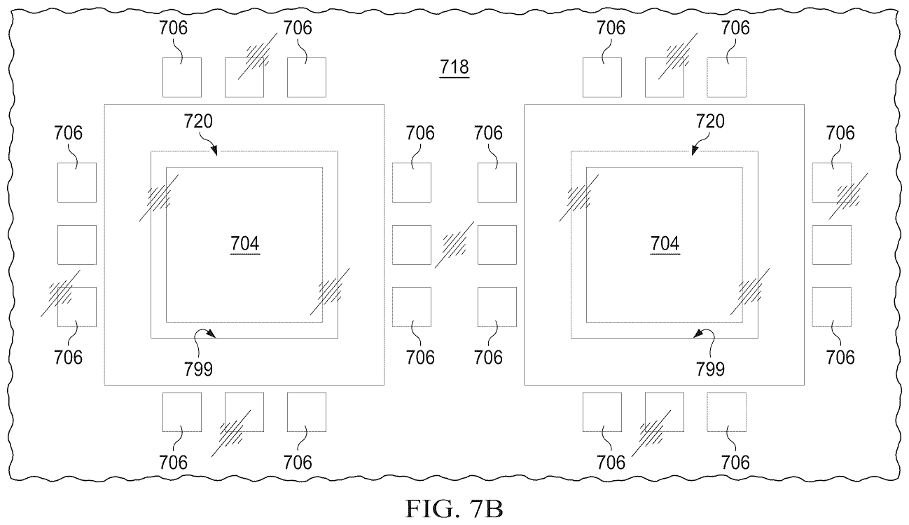

FIG. 6 is a flow diagram of a method 600 for manufacturing a MEMS device in accordance with various examples described herein. FIGS. 7A-14B are process flow diagrams for manufacturing a MEMS device in accordance with various examples described herein. Accordingly, FIGS. 6 and 7A-14B are now described in parallel.

The method 600 may include sawing through a first segment of a semiconductor interposer to form a first opening and not sawing through a second segment of the semiconductor interposer (602). The semiconductor interposer is coupled to one or more oxide layers (602). The one or more oxide layers are coupled to a bondline, and the bondline may be coupled to a semiconductor wafer (602). The bondline may circumscribe a MEMS element on the semiconductor wafer, with the bondline being between the MEMS element and a first bond pad on the semiconductor wafer (602).

FIGS. 7A and 7B are cross-sectional and top-down views, respectively, of an initial wafer-stage structure that can be processed as described below to manufacture a MEMS device, such as MEMS devices 250, 350, and 450. FIGS. 7A and 7B depict a wafer 702 (e.g., silicon wafer or gallium nitride wafer). The wafer 702 is representative of the semiconductor dies 202, 302, and 402, but prior to singulation. One or more devices 704, which are representative of the one or more devices 204, 304, and 404, are positioned on and/or in the wafer 702. Bond pads 706, representative of the bond pads 206, 306, and 406, are also on the wafer 702. Bondlines 746, representative of the bondlines 346 and 446, are also positioned on the wafer 702. As shown, each bondline 746 is between a bond pad 706 and the one or more devices 704. Multiple bond pads 706 are positioned between each consecutive pair of bondline 746. Each of the bondline 746 circumscribes a different instance of the one or more devices 704. A structure 799 is coupled to the bondline 746 and is suspended above the bond pads 706. The structure 799 may include, for example, a semiconductor interposer (e.g., semiconductor interposers 340, 440), one or more oxide layers (e.g., oxide layers 336, 338, 342, 344, 436, 438, 442, 444). Some of these oxide layers may be positioned above the semiconductor interposer in the structure 799, and some of the oxide layers may be positioned below the semiconductor interposer in the structure 799. A glass cap 718, representative of caps 218, 318, and 418, is positioned on the structure 799 and may be covered by one or more coating layers, with one coating layer optionally on the bottom surface of the glass cap 718 facing the one or more devices 704, and the other coating layer optionally on the top surface of the glass cap 718 facing away from the one or more devices 704 and covered by a protective film (e.g., photoresist, silicon dioxide, silicon nitride) to protect the coating layer during the plasma etch processes described below. Similarly, a protective structure, which in some examples may include photoresist, silicon dioxide, or silicon nitride, may optionally be provided on the wafer 702 to protect the wafer 702 during plasma etching. The various structures of FIG. 7A described above define cavities 720, which are representative of cavity 220. The cavities 220, 720 may be sealed cavities, such as hermitic cavities sealed by bondlines (e.g., bondlines 211, 746).

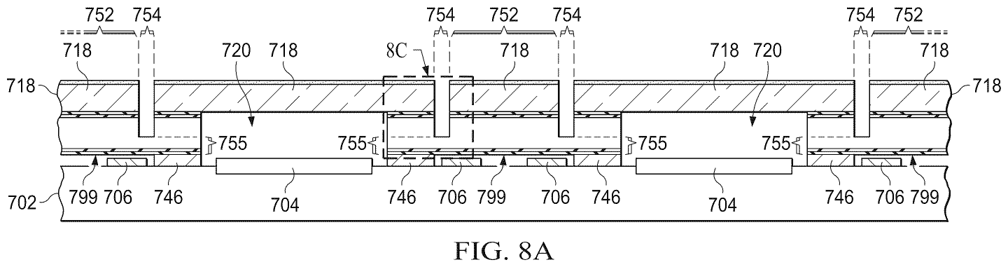

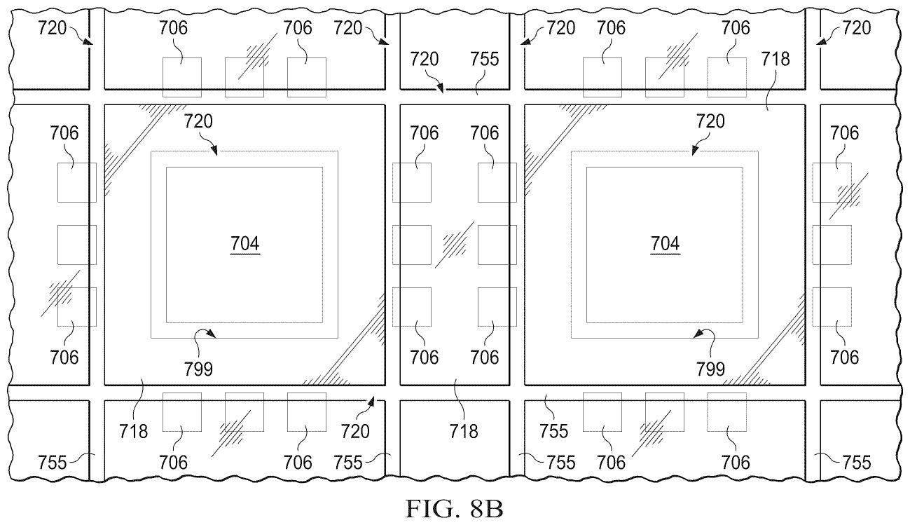

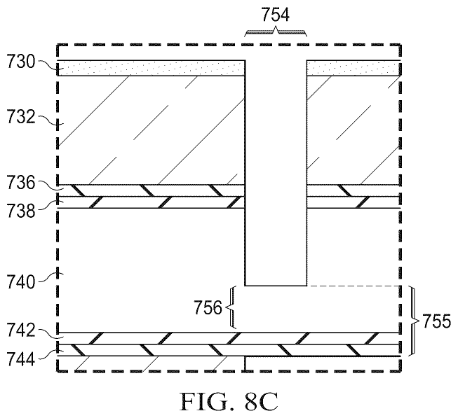

FIGS. 8A-8C are cross-sectional, top-down, and cross-sectional views, respectively, of the structure of FIGS. 7A and 7B, except that a mechanical or laser saw has been used to form first openings 754 in the glass cap 718 and in the structure 799, as shown. The glass cap 718 may thus be referred to as a sawn glass cap. The first openings 754 do not extend completely through the full thickness of the structure 799. Rather, the first openings 754 extend through any oxide layers that may be present at the top of the structure 799, proximal to the glass cap 718, and through part of the semiconductor interposer in the structure 799. The remaining thickness of the structure 799 below the first opening 754 that is not cut is the same as the distance 339 plus the combined thickness of the oxide layers 342, 344 (FIG. 3), and is the same as the distance 439 plus the combined thickness of the oxide layers 442, 444 (FIG. 4). The sawing produces structures 752 that are mechanically supported by structures 755, which are located below the first openings 754. The structure 799 may be at least five times thicker than the structure 755.

FIG. 8C is a more detailed cross-sectional view of example portions of the structures shown in FIGS. 8A and 8B. In particular, the first opening 754 extends through the coating layer 730, the glass cap 732, the oxide layers 736 and 738, and part of the semiconductor interposer 740. The first opening 754 does not extend through the entire thickness of the semiconductor interposer 740, as shown, nor does the first opening 754 extend through the oxide layers 742 or 744. The second segment 756 of the semiconductor interposer 740 is below the first opening 754. The structure 755 includes the second segment 756, as well as the portions of the oxide layers 742 and 744 below the first opening 754 and the second segment 756.

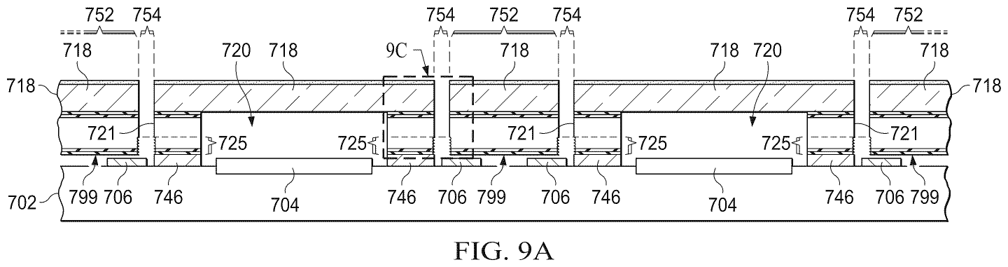

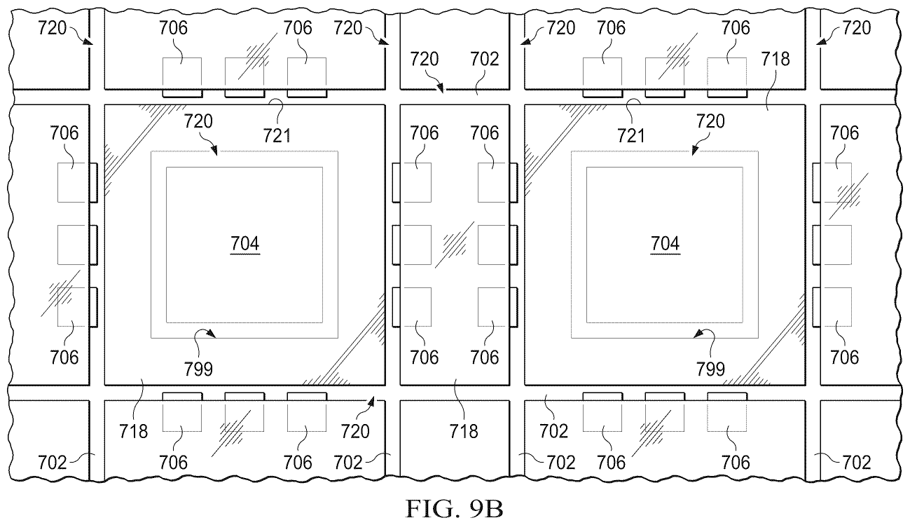

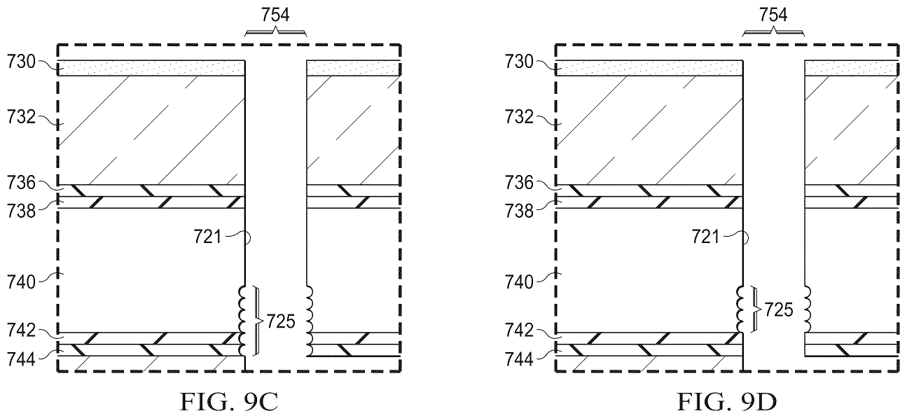

The method 600 may include plasma etching (e.g., a silicon dry reactive ion etching technique, such as a Bosch process; non-Bosch processes) through the second segment of the semiconductor interposer using the first opening to form a second opening (604), and forming a third opening in the one or more oxide layers using the first and second openings (606). Together, the first, second, and third openings form a through-hole that extends through all layers of the structure, including the glass, interposer, oxides, and any additional layers contacting these layers, thereby exposing the first bond pad. FIGS. 9A-9D are cross-sectional, top-down, cross-sectional, and cross-sectional views, respectively, of the structure of FIGS. 8A-8C, except that the structures 755 have been removed by a plasma etching technique, leaving striations 725 on exterior surfaces 721. (As mentioned herein, non-Bosch plasma etching techniques also may be used, in which case the striations may be absent.) Specifically, as FIG. 9C shows, the second segment 756 of the semiconductor interposer 740 is removed by plasma etching to form a second opening, with the striations 725 remaining as evidence that plasma etching was used. The striations 725 are present where the second segment 756 was previously located, and, as shown, the striations 725 extend along the exterior surface 721 on the semiconductor interposer 740. The striations 725 may have the same features and properties as the striations 325 and/or 425 described above. The third opening is formed in the oxide layers 742, 744 through the first and second openings by either the plasma etching technique or by a liquid jet technique (e.g., water jet technique). When the oxide layers 742 and 744 are removed by a plasma etching technique, the striations 725 are present on the exterior surface 721 at the level of the oxide layers 742 and 744, as FIG. 9C shows. However, when the oxide layers 742 and 744 are removed by a liquid jet technique, the striations 725 are not present on the exterior surface 721 at the level of the oxide layers 742 and 744, as FIG. 9D shows.

In FIGS. 9C and 9D, plasma etching is achieved through the first opening 754 (FIGS. 8A and 9A). To facilitate plasma etching through the first opening 754, the glass cap 718 operates as a mask, which is patterned by the first openings 754. When the plasma etch is performed, the glass cap 718 protects the structures below the glass cap 718, while allowing the etching to occur in the structures accessible by the first openings 754.

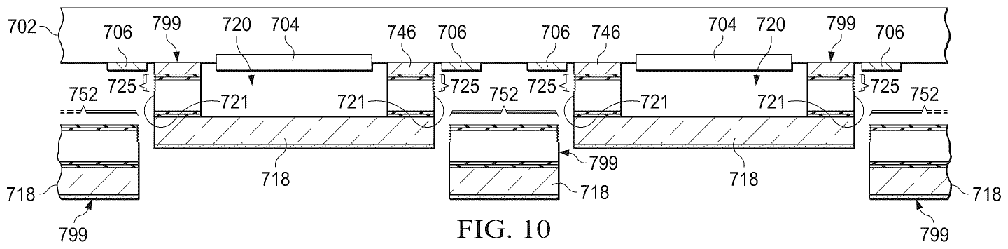

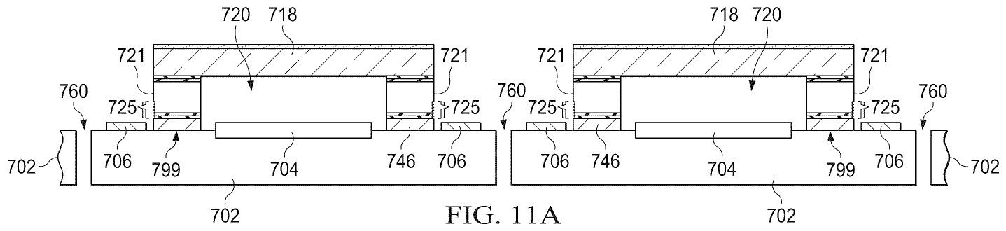

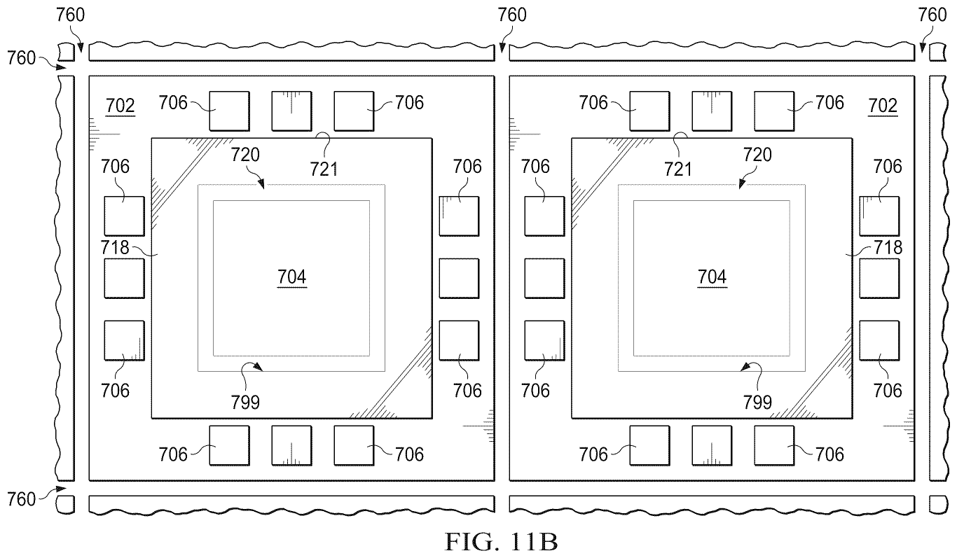

Forming the first, second, and third openings as described above results in the structures 752 (FIG. 8A) being released. The structures 752 may be removed by inversion, as FIG. 10 shows. The method 600 may include sawing through the semiconductor wafer between the first bond pad and a second bond pad on the semiconductor wafer (608). FIGS. 11A and 11B are cross-sectional and top-down views of the structure of FIG. 10A, except that the wafer 702 has been sawn, as numeral 760 indicates. The resulting singulated structures may be mounted on and wire bonded to a substrate (610), such as a ceramic substrate, and the wire bonds may be covered by a protective layer, such as an epoxy (612), resulting in the example MEMS device 250 of FIGS. 2A-2E. Use of the manufacturing techniques described above to form the example MEMS devices 250 results in greater manufacturing yield, because the techniques protect the bond pad shelves from damage.

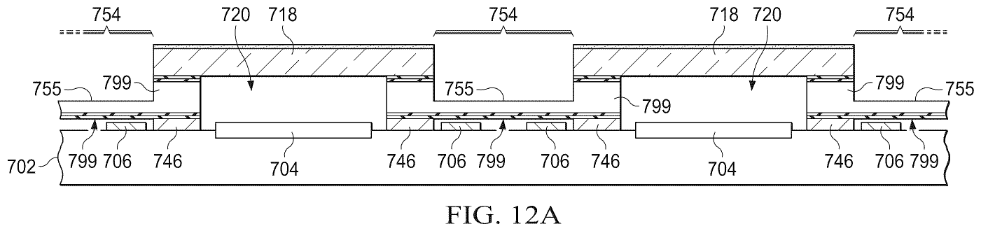

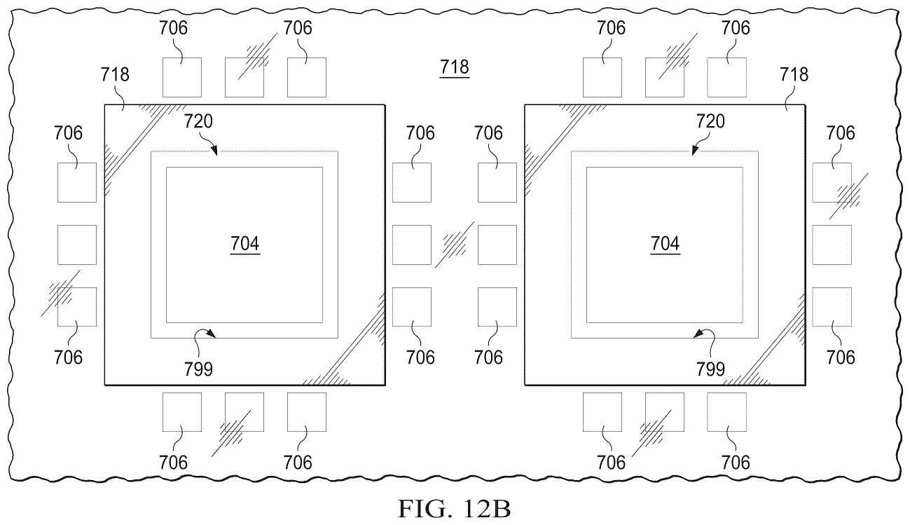

The process flow of FIGS. 7A-11B assume that the initial sawing technique of step 602 (FIG. 6) is performed by a standard-width dicing saw or standard-width laser saw, resulting in the relatively narrow first openings 754 shown in FIG. 8A. However, in some examples, the initial sawing technique of step 602 may be performed by a hog-out saw, which forms substantially wider cuts than does a standard-width saw. FIGS. 12A-14B depict a process flow in which a hog-out saw is used to manufacture MEMS devices, such as MEMS devices 250, 350, and 450. In particular, FIGS. 12A and 12B are cross-sectional and top-down views of structures nearly identical to those of FIGS. 8A and 8B, except that a hog-out saw is used to create the first opening 754, resulting in the first opening 754 being substantially wider than the first opening 754 is in FIGS. 8A and 8B. Using the hog-out saw leaves structures 755 remaining, as shown. Each of the structures 755, including the semiconductor interposer within the structures 755, has an approximately uniform thickness along the entirety of its length between the two bondlines 746.

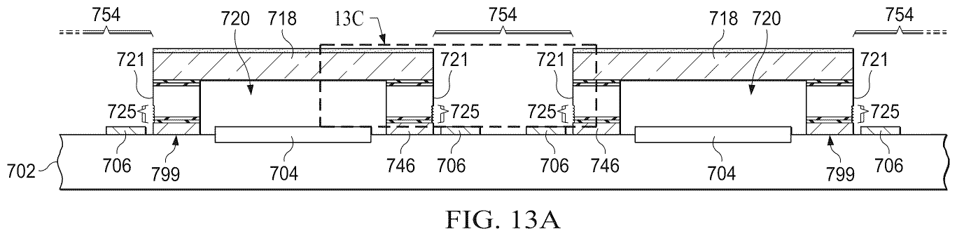

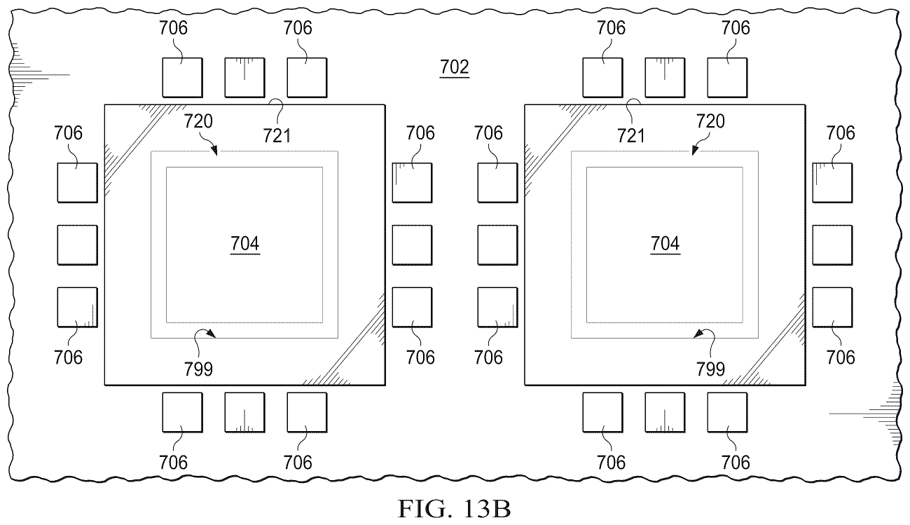

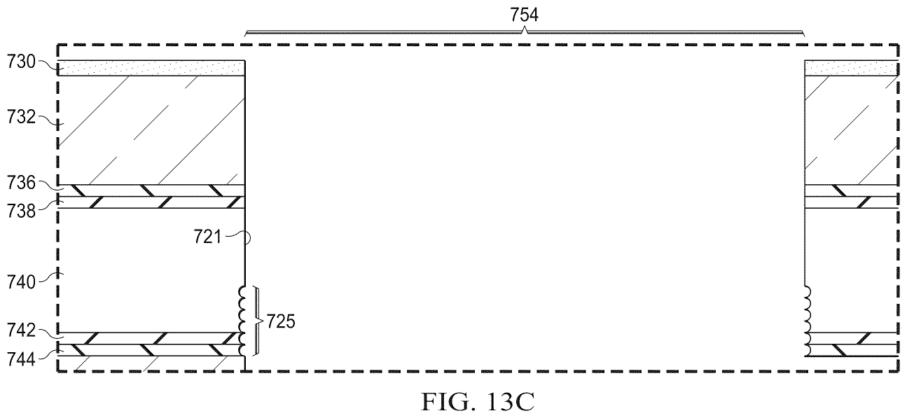

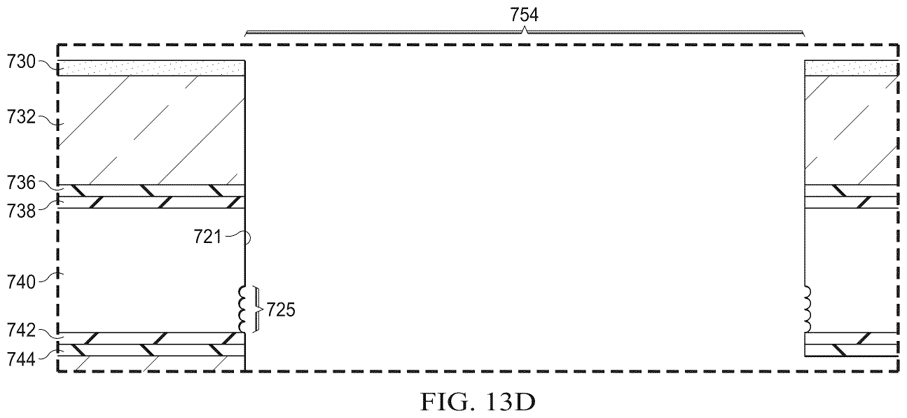

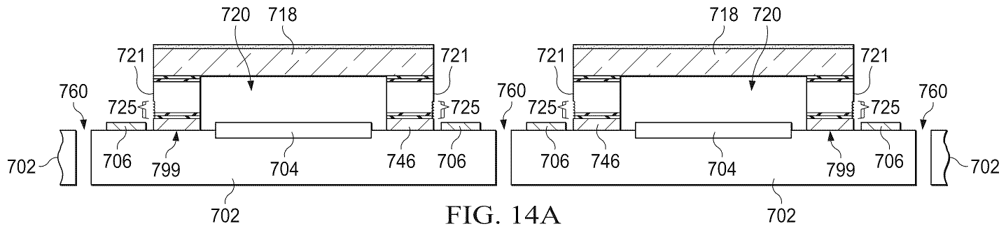

Steps 604 and 606 of FIG. 6, described in detail above, are performed to remove the structures 755, as the cross-sectional and top-down views of FIGS. 13A and 13B show. The semiconductor interposer portion of each structure 755 may be removed by plasma etch, and the oxide layers of the structure 755 that are below the semiconductor interposer portion may be removed by either plasma etch or liquid (e.g., water) jet techniques. FIG. 13C is a detailed, cross-sectional view of portions of the structure of FIGS. 13A and 13B if a plasma etch technique is used to cut through the entire thickness of the structure 755, including the oxide layers 742 and 744. In contrast, FIG. 13D is a detailed, cross-sectional view of portions of the structure of FIGS. 13A and 13B is a plasma etch technique is applied through the first opening 754 to cut through the second segment 756 of the semiconductor interposer 740 and a liquid jet technique is applied through the first and second openings to cut through the portions of the oxide layers 742 and 744 directly below the first opening 754 and the second segment 756. Consequently, as FIG. 13D shows, the exterior surface 721 of the second segment 756 bears the striations 725, but the oxide layers 742 and 744 do not bear the striations 725. Use of the hog-out saw is beneficial at least because, when the oxide layers structures 755 are removed by either plasma etch or a plasma etch and liquid jet combination, there remains no structure 752 that can be dislodged and damage the underlying bond pads 706.

In FIGS. 13C and 13D, plasma etching is achieved through the first opening 754 (FIGS. 8A and 9A). To facilitate plasma etching through the first opening 754, the glass cap 718 operates as a mask, which is patterned by the first openings 754. When the plasma etch is performed, the glass cap 718 protects the structures below the glass cap 718, while allowing the etching to occur in the structures accessible by the first openings 754.

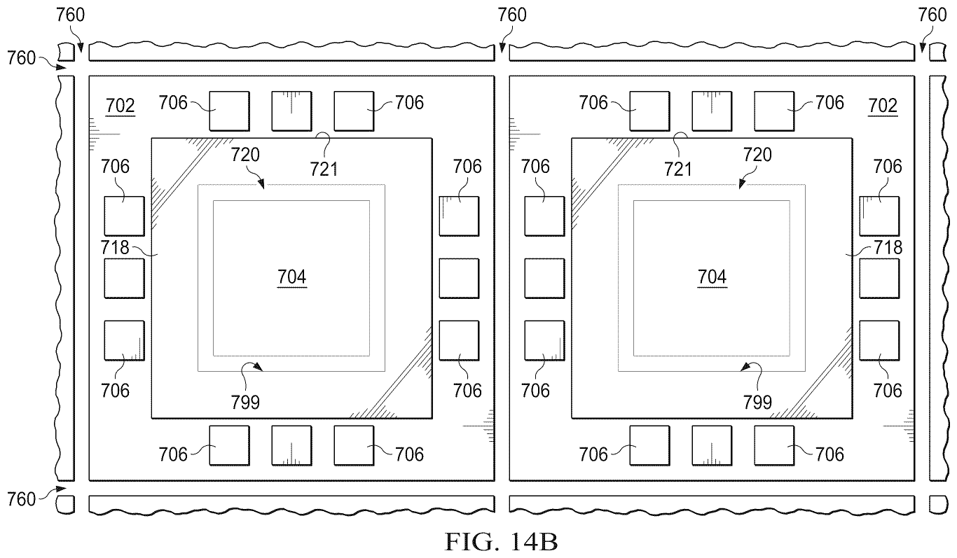

Step 608 of FIG. 6 entails the singulation of the semiconductor wafer, as described in detail above. FIGS. 14A and 14B are cross-sectional and top-down views of the structure of FIGS. 13A and 13B, except that a saw is used to singulate the wafer 702, as numeral 760 indicates. The resulting structure may be wire bonded to a substrate (e.g., a ceramic substrate) and the bond wires may be covered in a protective layer (e.g., epoxy) to produce a MEMS device, such as the MEMS devices 250, 350, 450 described above.

As described above, plasma etching techniques used during the manufacturing process result in the formation of striations, such as the striations 325 shown in FIGS. 3A-3C and the striations 425 shown in FIGS. 4A-4C. As also described above, the plasma etching technique that forms such striations is sometimes referred to as the Bosch process, which is a type of silicon deep reactive ion etching technique. The scope of this disclosure, however, is not limited to the Bosch process. For example, another type of silicon deep reactive ion etching technique known as a non-Bosch process also may be useful to perform the specific etches attributed herein to the Bosch plasma etching technique, such as in the method 600. In a non-Bosch process, a protective material (e.g., hexafluorobutadiene (C₄F₆)) is deposited on a sidewall of the opening being etched and, simultaneously, ions are used to etch the bottom of the opening. The non-Bosch process may result in smooth sidewalls of the opening being etched. Thus, for example, the areas described herein as having the striations 325 and 425 may instead have smooth surfaces as a result of the non-Bosch process. Other etching techniques are contemplated and included in the scope of this disclosure.

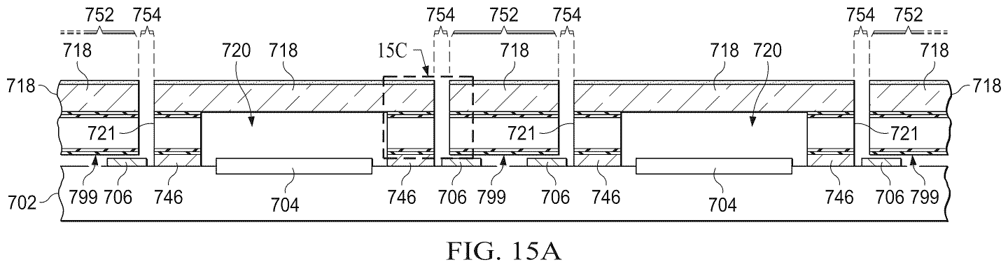

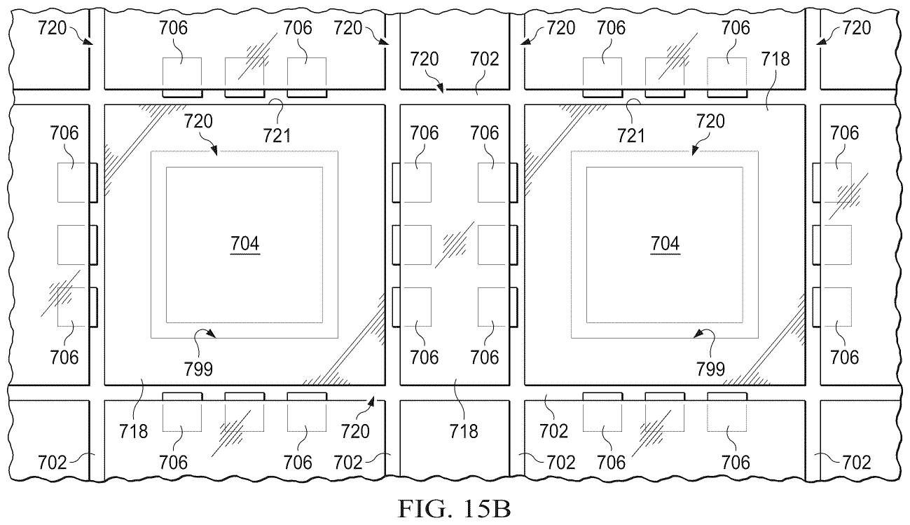

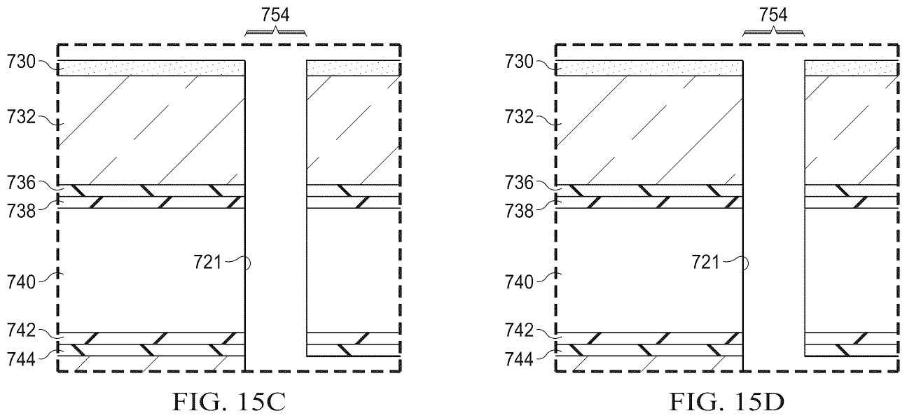

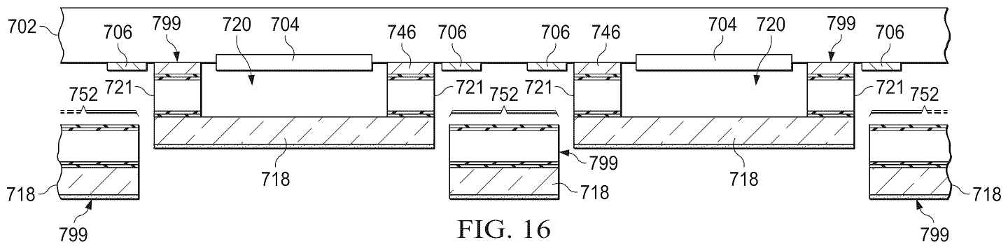

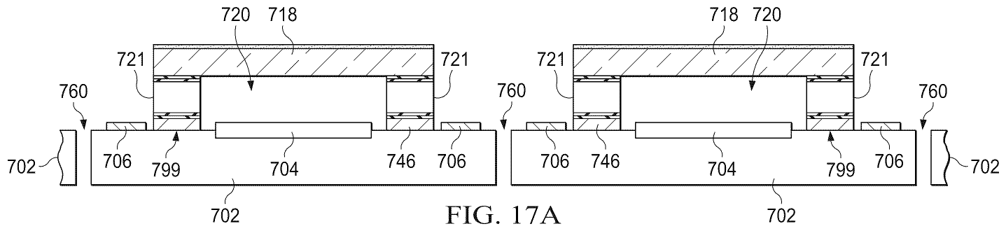

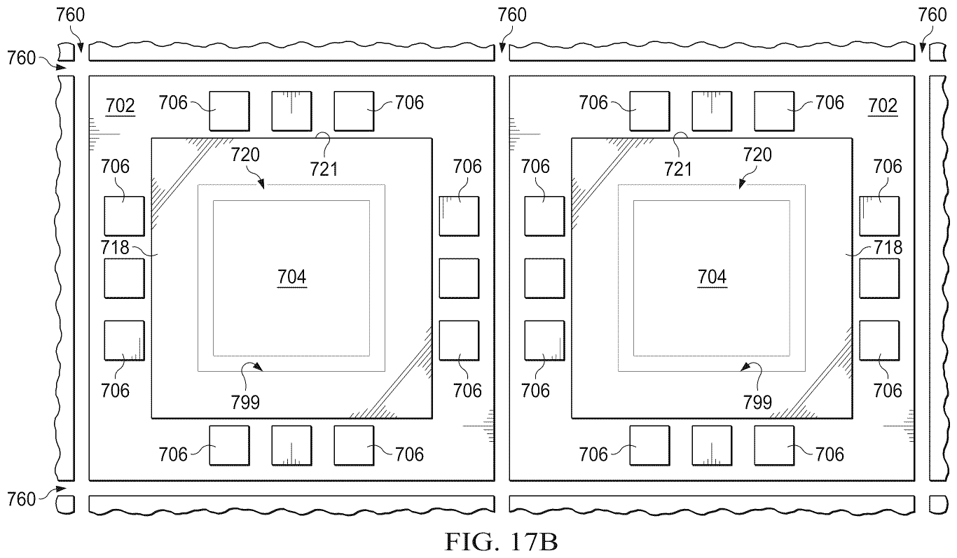

FIGS. 7A-8C and 15A-17B depict an example manufacturing technique process flow that uses a non-Bosch plasma etch. Such a manufacturing technique may begin as depicted in FIGS. 7A-8C. In the various views of FIGS. 15A-15D, the structure of FIGS. 8A-8C is etched just as described above for the Bosch process with reference to FIGS. 9A-9D, except that a non-Bosch process is used, leaving a lack of surface striations, as shown. FIG. 16 is similar to FIG. 10, except that structures lack striations because a non-Bosch process is used. FIGS. 17A and 17B are identical to FIGS. 11A and 11B, except that the structures lack striations because a non-Bosch process is used. A process similar to that shown in FIGS. 7A-8C and 15A-17B, except with the use of a hogout saw as described with reference to FIGS. 12A-14B, is also contemplated and included in the scope of this disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. An electronic device, comprising:
a semiconductor die including circuitry;
a microelectromechanical systems (MEMS) element on the semiconductor die and coupled to the circuitry;
a bond pad on the semiconductor die and coupled to the circuitry;
a bondline on the semiconductor die between the MEMS element and the bond pad, the bondline circumscribing the MEMS element; and
a semiconductor interposer coupled to the bondline and having a striated exterior surface facing away from the MEMS element.

2. The electronic device of claim 1, further comprising one or more oxide layers in between the semiconductor interposer and the bondline, wherein an exterior surface of the one or more oxide layers faces away from the MEMS element and is striated.

3. The electronic device of claim 2, wherein the one or more oxide layers has a total thickness ranging from 1 micron to 10 microns.

4. The electronic device of claim 2, wherein a boundary between striated and non-striated segments of the exterior surface of the semiconductor interposer is a distance from the one or more oxide layers, the distance ranging from 1 micron to 925 microns.

5. The electronic device of claim 4, wherein the striated segment of the exterior surface of the semiconductor interposer is between the non-striated segment of the exterior surface of the semiconductor interposer and the one or more oxide layers.

6. The electronic device of claim 1, wherein the striated exterior surface of the semiconductor interposer includes structural features caused by a plasma etching technique.

7. The electronic device of claim 6, wherein the structural features include multiple concavities.

8. The electronic device of claim 7, wherein each of the multiple concavities is approximately 50 nanometers in height.

9. An electronic device, comprising:
a semiconductor die including circuitry;
mirrors on the semiconductor die;
a bond pad on the semiconductor die and coupled to the circuitry;
a bondline on the semiconductor die between the bond pad and the mirrors, the bondline circumscribing the mirrors;
one or more oxide layers coupled to a top surface of the bondline, the one or more oxide layers having striated exterior surfaces facing away from the mirrors;
a semiconductor interposer coupled to the one or more oxide layers and having a striated exterior surface facing away from the mirrors; and
a glass cap coupled to the semiconductor interposer and positioned over the mirrors.

10. The electronic device of claim 9, wherein the striated exterior surface of the semiconductor interposer and the striated exterior surface of the one or more oxide layers include structural features caused by a plasma etching technique.

11. The electronic device of claim 10, wherein the structural features include multiple concavities.

12. The electronic device of claim 11, wherein each of the multiple concavities is approximately 50 nanometers in height.

13. The electronic device of claim 9, wherein a boundary between striated and non-striated segments of the exterior surface of the semiconductor interposer is a distance from the one or more oxide layers, the distance ranging from 1 micron to 925 microns.

14. The electronic device of claim 13, wherein the striated segment of the exterior surface of the semiconductor interposer is between the non-striated segment of the exterior surface of the semiconductor interposer and the one or more oxide layers.

15. A method for manufacturing a microelectromechanical systems (MEMS) device, comprising:
sawing through a first portion of a semiconductor interposer to form a first opening, the semiconductor interposer coupled to one or more oxide layers, the one or more oxide layers coupled to a bondline, the bondline coupled to a semiconductor wafer, the bondline circumscribing a MEMS element on the semiconductor wafer, the bondline between the MEMS element and a first bond pad on the semiconductor wafer;
plasma etching through a second portion of the semiconductor interposer using the first opening to form a second opening;
forming a third opening in the one or more oxide layers using the first and second openings to expose the first bond pad; and
sawing through the semiconductor wafer between the first bond pad and a second bond pad on the semiconductor wafer.

16. The method of claim 15, wherein forming the third opening comprises using one of a plasma etching technique and a water jet technique.

17. The method of claim 15, wherein the plasma etching is a silicon dry reactive ion etching technique and is one of a Bosch process and a non-Bosch process.

18. The method of claim 15, wherein, prior to the plasma etching to form the second opening, the sawing through the first portion of the semiconductor interposer produces a structure comprising a second bondline, the first and second bond pads between the bondline and the second bondline, wherein the semiconductor interposer between the bondline and the second bondline has an approximately uniform thickness.

19. The method of claim 15, wherein, prior to the plasma etching to form the second opening, the sawing through the first portion of the semiconductor interposer produces a structure comprising a second bondline, the first and second bond pads between the bondline and the second bondline, wherein the semiconductor interposer between the bondline and the second bondline has a first portion and a second portion that is at least five times thicker than the first portion.

20. The method of claim 15, further comprising sawing through a glass cap prior to sawing through the first portion of the semiconductor interposer to form a sawn glass cap, and using the sawn glass cap as a mask when performing the plasma etching.
